(19) United States
(12) Patent Application Publication
(10) Pub. No.: US 2013/0162110 A1
(43) Pub. Date: Jun. 27, 2013

(54) PIEZOELECTRIC VIBRATOR AND METHOD OF MANUFACTURING THE SAME

(71) Applicant: Samsung Electro-Mechanics Co., Ltd., Suwon-si (KR)

(72) Inventors: Jong Pil LEE, Suwon-si (KR); Sang Yeob CHA, Suwon-si (KR)

(73) Assignee: SAMSUNG ELECTRO-MECHANICS CO., LTD., Suwon-si (KR)

(21) Appl. No.: 13/692,589

(22) Filed: Dec. 3, 2012

(30) Foreign Application Priority Data
Dec. 1, 2011 (KR) 10-2011-0127481

(51) Int. Cl. H01L 41/04; H01L 41/332

(52) U.S. Cl. CPC H01L 41/04; H01L 41/332
USPC 310/370; 29/25.35

(57) ABSTRACT

There is provided a piezoelectric vibrator including: a base portion; a pair of arm portions extending from the base portion in parallel to each other; first recess portions formed in a length direction in upper surfaces of the pair of arm portions; and second recess portions formed in the length direction in lower surfaces of the pair of arm portions, wherein in a cross section of the pair of arm portions in a length-thickness direction, the first recess portions and the second recess portions may be disposed to be offset and spaced apart from one another by a predetermined interval in a width direction of the pair of arm portions. A piezoelectric vibrator having low resistance and high quality coefficient can be implemented, and thus, a stable frequency can be provided.

### CROSS-REFERENCE TO RELATED APPLICATIONS

This application claims the priority of Korean Patent Application No. 10-2011-0127481 filed on Dec. 1, 2011, in the Korean Intellectual Property Office, the disclosure of which is incorporated herein by reference.

### BACKGROUND OF THE INVENTION

1. Field of the Invention

The present invention relates to a piezoelectric vibrator having a stable frequency implemented therein through a resistance value in an internal electrical field flow process being lowered, and a simplified manufacturing process.

2. Description of the Related Art

In general, a piezoelectric element is an element that vibrates when an outside voltage is applied thereto according to a piezoelectric phenomenon, and generates a frequency through the vibrations thereof. A piezoelectric vibrator may obtain a stable frequency, is used for various purposes such as a frequency oscillator, a frequency regulator, a frequency converter, and the like. In particular, a piezoelectric vibrator is used in an oscillation circuit of a small information device such as a computer (a hard disk drive thereof), an integrated circuit (IC) card or the like, a communications device, or is used as a key component in a device for a reference of a signal.

A piezoelectric vibrator uses crystal having excellent piezoelectric characteristics as a piezoelectric material, and here, crystal serves as a stable mechanical vibration generator.

In this case, a crystal is required to have low phase noise, a high Q (Quality) value, and low frequency variation over time and with changes in an environment . Here, the Q value represents band selection characteristics in a resonator, a wave filter, an oscillator, and the like, also called a quality coefficient. The Q value is calculated as a ratio of a center frequency to a 3 dB bandwidth, and as the Q value is increased, an oscillator has better frequency selection characteristics.

Among various types of piezoelectric vibrator, a tuning fork-type piezoelectric vibrator includes a pair of vibration arm portions disposed to be parallel and a base portion fixing the pair of vibration arm portions, and electrodes are formed on outer surfaces of the vibration arm portions and the base portion. When a certain voltage is applied to the piezoelectric vibrator, a resonance frequency is generated in a direction toward the pair of vibration arm portions or away therefrom.

Recently, as functions of mobile communications terminals such as mobile phones, and the like, have become diversified and complex, components provided therein have been required to be smaller and thinner. Thus, a piezoelectric vibrator constituting a piezoelectric vibrator is required to be smaller.

However, in operating the tuning fork-type piezoelectric vibrator, when an electrical field component is relatively large, a resistance value is reduced, but when a piezoelectric vibrator is reduced in size, an electrical field component is reduced while a resistance value is increased, making it difficult to implement a stable frequency value.

Also, when the resistance value is increased, it is difficult to operate a piezoelectric vibrator at low power.

### SUMMARY OF THE INVENTION

An aspect of the present invention generates a stable frequency value by increasing an electrical field effect in a relatively small piezoelectric vibrator. Also, a unit cost can be reduced and process efficiency can be enhanced by simplifying a piezoelectric vibrator manufacturing process.

According to an aspect of the present invention, there is provided a piezoelectric vibrator including: a base portion; a pair of arm portions extending from the base portion in parallel to each other; first recess portions formed in a length direction in upper surfaces of the pair of arm portions; and second recess portions formed in the length direction in lower surfaces of the pair of arm portions, wherein in a cross section of the pair of arm portions in a length-thickness direction, the first recess portions and the second recess portions may be disposed to be offset and spaced apart from one another by a predetermined interval in a width direction of the pair of arm portions.

The first recess portions or the second recess portions may be provided in plural.

The second recess portions may be formed in pairs in the respective lower surfaces of the pair of arm portions such that they are parallel to each other.

Electrodes may be formed on outer surfaces of the base portion and the pair of arm portions.

According to another aspect of the present invention, there is provided a method of manufacturing a piezoelectric vibrator, the method including: preparing a substrate; forming a base portion and a pair of arm portions extending from the base portion in parallel to each other; forming first recess portions in a length direction in upper surfaces of the pair of arm portions; and forming second recess portions in the length direction in lower surfaces of the pair of arm portions, wherein in a cross section of the pair of arm portions in a length-thickness direction, the first recess portions and the second recess portions may be disposed to be offset and spaced apart from one another by a predetermined interval in a width direction of the pair of arm portions.

The first recess portions or the second recess portions may be provided in plural.

The second recess portions may be formed in pairs in the respective lower surfaces of the pair of arm portions such that they are parallel to each other.

The method may further include forming an electrode material on outer surfaces of the base portion and the pair of arm portions.

The pair of arm portions and the first and second recess portions may be formed through etching with a gas in a plasma state.

The forming of the pair of arm portions and the forming of the first and second recess portions may be performed simultaneously.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a perspective view schematically illustrating a piezoelectric vibrator according to an embodiment of the present invention;

FIG. 2 is a cross-sectional view showing an example of the piezoelectric vibrator according to the embodiment of the present invention, taken along line A-A′ of FIG. 1;

FIG. 3 is a cross-sectional view showing another example of the piezoelectric vibrator according to the embodiment of the present invention, taken along line A-A′ of FIG. 1;

FIG. 4 is a cross-sectional view showing another example of the piezoelectric vibrator according to the embodiment of the present invention, taken along line A-A′ of FIG. 1;

FIG. 5A to 5D are a view illustrating a method of manufacturing a piezoelectric vibrator according to an embodiment of the present invention.

### DETAILED DESCRIPTION OF THE EMBODIMENTS

Hereinafter, embodiments of the present invention will be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like elements.

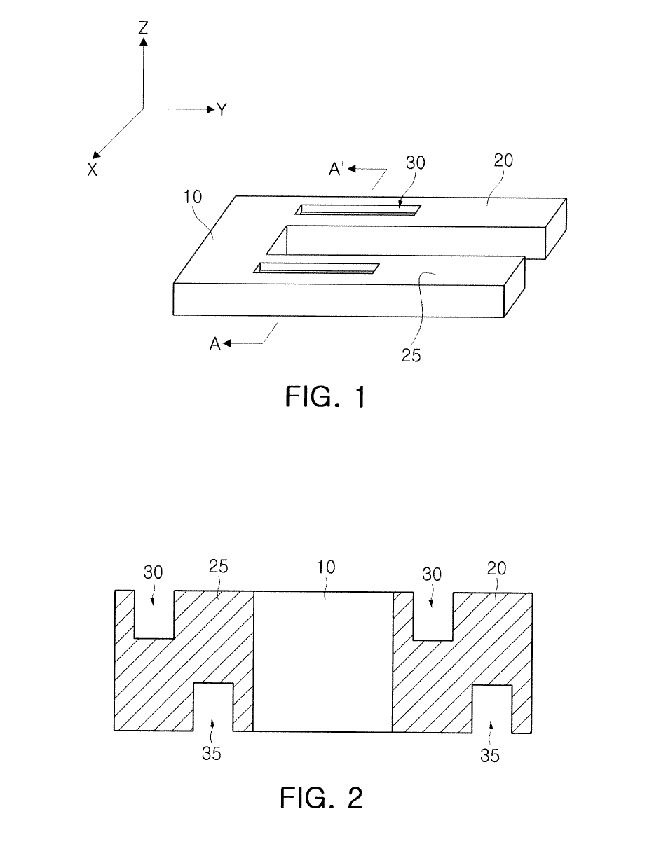

In a piezoelectric vibration according to the present embodiment, a ‘length direction’ is defined as a Y direction, a ‘thickness direction’ is defined as a Z direction, and ‘width direction’ is defined as an X direction in FIG. 1.

FIG. 1 is a perspective view schematically illustrating a piezoelectric vibrator according to an embodiment of the present invention.

FIGS. 2 through 4 are cross-sectional views showing examples of the piezoelectric vibrator according to the embodiment of the present invention, taken along line A-A′ of FIG. 1, viewed in the Y direction.

Referring to FIGS. 1 and 2, a piezoelectric vibrator according to an embodiment of the present invention includes a base portion 10, a pair of arm portions 20 and 25 extending from the base portion 10 in parallel to each other, first recess portions 30 formed in the length direction in upper surfaces of the pair of arm portions 20 and 25, and second recess portions 35 formed in the length direction in lower surfaces of the pair of arm portions, and in this case, in a cross section of the pair of arm portions in a length-thickness direction, the first recess portions 30 and the second recess portions 35 are disposed to be offset and spaced apart from one another by a certain interval in a width direction of the pair of arm portions.

In the section taken along line A-A′, the first recess portions 30 and the second recess portions 35 may be spaced apart from one another at a certain interval in the X direction, but the present invention is not limited thereto and the first recess portions 30 may be spaced apart from the second recess portions 35 such that the first recess portions 30 do not overlap with the second recess portions 35 when the first recess portions 30 extend in the thickness direction.

Electrodes may be formed on outer surfaces of the base portion and the pair of arm portions.

A material used for forming the electrodes may include silver (Ag), gold (Au), nickel (Ni), copper (Cu), or the like, and the piezoelectric vibrator may include first and second electrodes formed in an opposing manner on upper and lower surfaces of the base portion 10 and the pair of arm portions 20 and 25.

Referring to FIG. 2, a piezoelectric vibrator according to the embodiment of the present invention may include a single first recess portion 30 formed in the upper surface of the arm portion 20 and a single second recess portion 35 formed in the lower surface of the arm portion 20.

The first recess portion or the second recess portion may be provided in plural, and the second recess portions are formed in pairs in the respective lower surfaces of the pair of arm portions such that they are parallel to each other, but the present invention is not limited thereto.

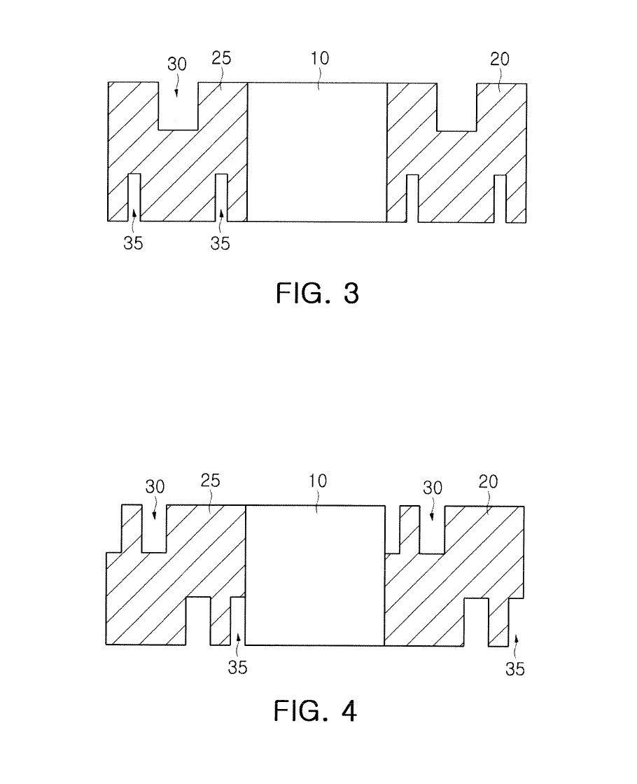

Referring to FIG. 3, the piezoelectric vibrator according to the embodiment of the present invention may include the single first recess portion 30 formed in the upper surface of the arm portion 20 and two second recess portions 35 formed in the lower surface of the arm portion 20.

In the cross section of the pair of arm portions in the length-thickness direction, the first recess portion 30 and the second recess portions 35 are disposed to be offset and spaced apart by a certain interval in the width direction of the pair of arm portions. A virtual first recess portion formed by extending the first recess portion 30 in the thickness direction may be formed between the two second recess portions 35.

Referring to FIG. 4, the piezoelectric vibrator according to the embodiment of the present invention may include two first recess portions 30 and two second recess portions 35 formed in the upper surface and the lower surface of the arm portion 20, respectively.

When a voltage is applied to electrodes, an electrical field flow is generated. Thus, the recess portions 30 and 35 are formed in the upper and lower surfaces of the arm portion 20 of the piezoelectric vibrator so as to be asymmetrically with respect to each other, whereby an electrical field component can be increased. Accordingly, a resistance value generated in the piezoelectric vibrator can be lowered and a Q value as a quality coefficient can be increased.

Thus, a piezoelectric vibrator having a small size while providing a stable frequency value with low power consumption can be implemented.

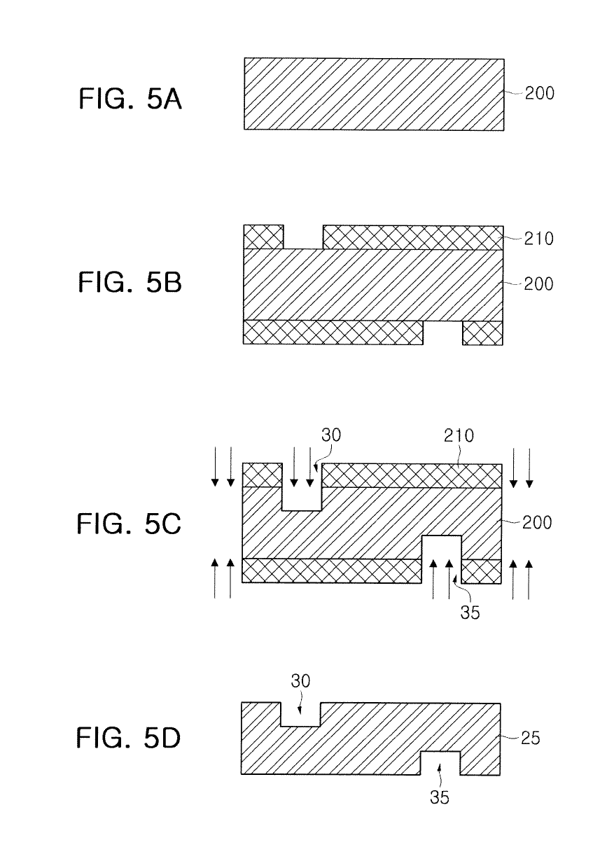

FIG. 5 is a view illustrating a method of manufacturing a piezoelectric vibrator according to an embodiment of the present invention. Specifically, FIGS. 5A through 5D schematically illustrate operations of forming recess portions in one of a pair of arm portions.

Referring to FIG. 5, the method of manufacturing a piezoelectric vibrator according to an embodiment of the present invention includes: preparing a substrate; forming a base portion and a pair of arm portions extending from the base portion in parallel to each other; forming first recess portions in a length direction in upper surfaces of the pair of arm portions; and forming second recess portions in the length direction in lower surfaces of the pair of arm portions, wherein in a cross section of the pair of arm portions in a length-thickness direction, the first recess portions and the second recess portions are disposed to be offset and spaced apart from one another by a certain interval in a width direction of the pair of arm portions.

The first recess portions or the second recess portions may be provided in plural.

The method may further include: forming an electrode material on outer surfaces of the base portion and the pair of arm portions.

In the method of manufacturing a piezoelectric vibrator according to an embodiment of the present invention, characteristics of the piezoelectric vibrator the same as those of the piezoelectric vibrator according to the aforementioned embodiment of the present invention will hereinafter be omitted.

In the manufacturing method, the pair of arm portions, the first recess portions, and the second recess portions may be formed through etching with a gas in a plasma state.

Also, the forming of the pair of arm portions and the forming of the first and second recess portions may be performed simultaneously.

According to the embodiment of the present invention, a substrate 200 may be prepared, and masks 210 having openings exposing regions to be etched may be formed on upper and lower surfaces of the substrate 200.

The regions exposed through the openings of the masks 210 may be etched by supplying a gas in a plasma state to the upper and lower surfaces of the substrate 200, on which the masks 210 are formed.

In the related art, in the case of forming recess portions in the upper and lower surfaces of the arm portions, when a process is performed on a wafer with the same pressure as that of a gas jet to form arm portions of a piezoelectric vibrator, a defect arises in that the recesses in the upper and lower surfaces of the arm portions are overlapped, thereby forming an opening in the arm portion.

Thus, in the related art, after the process of forming the arm portions of the piezoelectric vibrator is performed on a wafer through a method of performing etching by supplying a gas in a plasma state, a process of forming recess portions in the arm portions is performed.

According to the embodiment of the present invention, the first recess portions 30 and the second recess portions 35 are disposed to be offset and spaced apart by a certain interval in the width direction of the pair of arm portions 20 and 25, whereby the process of forming the arm portions 20 and 25 of the piezoelectric vibrator and the process of forming the recess portions 30 and 35 in the upper and lower surfaces of the arm portions 20 and 25 may be performed simultaneously.

Thus, in the embodiment of the present invention, the manufacturing process of the piezoelectric vibrator is simplified, and thus, unit cost can be reduced and process efficiency can be enhanced.

As set forth above, according to embodiments of the present invention, a electrical field effect is enhanced through designing a structure of a recess portion formed in an arm portion of the piezoelectric vibrator, and thus, a resistance value can be reduced. A piezoelectric vibrator having a low resistance value can exhibit a stable frequency value and have high reliability. Also, according to embodiments of the present invention, process efficiency can be enhanced by simplifying a manufacturing process.

While the present invention has been shown and described in connection with the embodiments, it will be apparent to those skilled in the art that modifications and variations can be made without departing from the spirit and scope of the invention as defined by the appended claims.

What is claimed is:

1. A piezoelectric vibrator comprising:
a base portion;
a pair of arm portions extending from the base portion in parallel to each other;
first recess portions formed in a length direction in upper surfaces of the pair of arm portions; and
second recess portions formed in the length direction in lower surfaces of the pair of arm portions,
wherein in a cross section of the pair of arm portions in a length-thickness direction, the first recess portions and the second recess portions are disposed to be offset and spaced apart from one another by a predetermined interval in a width direction of the pair of arm portions.

2. The piezoelectric vibrator of claim 1, wherein the first recess portions or the second recess portions are provided in plural.

3. The piezoelectric vibrator of claim 1, wherein the second recess portions are formed in pairs in the respective lower surfaces of the pair of arm portions such that they are parallel to each other.

4. The piezoelectric vibrator of claim 1, wherein electrodes are formed on outer surfaces of the base portion and the pair of arm portions.

5. A method of manufacturing a piezoelectric vibrator, the method comprising:
preparing a substrate;
forming a base portion and a pair of arm portions extending from the base portion in parallel to each other;
forming first recess portions in a length direction in upper surfaces of the pair of arm portions; and
forming second recess portions in the length direction in lower surfaces of the pair of arm portions,
wherein in a cross section of the pair of arm portions in a length-thickness direction, the first recess portions and the second recess portions are disposed to be offset and spaced apart from one another by a predetermined interval in a width direction of the pair of arm portions.

6. The method of claim 5, wherein the first recess portions or the second recess portions are provided in plural.

7. The method of claim 5, wherein the second recess portions are formed in pairs in the respective lower surfaces of the pair of arm portions such that they are parallel to each other.

8. The method of claim 5, further comprising forming an electrode material on outer surfaces of the base portion and the pair of arm portions.

9. The method of claim 5, wherein the pair of arm portions and the first and second recess portions are formed through etching with a gas in a plasma state.

10. The method of claim 5, wherein the forming of the pair of arm portions and the forming of the first and second recess portions are performed simultaneously.
